(19) United States
(12) Patent Application Publication
(10) Pub. No.: US 2013/0087517 A1
(43) Pub. Date: Apr. 11, 2013

(54) Supporting Device for a Tablet Personal Computer

(71) Applicant: Renkang ZHONG, Shenzhen (CN)

(72) Inventor: Renkang ZHONG, Shenzhen (CN)

(73) Assignee: ZHONG, Renkang; Shenzhen Paoluy Silicone Technology Co., Ltd

(21) Appl. No.: 13/347,703

(22) Filed: Jan. 11, 2012

(30) Foreign Application Priority Data
Oct. 10, 2011 (CN) 201120382131.2

(51) Int. Cl. H05K 7/18

(52) U.S. Cl. 211/26

(57) ABSTRACT

A supporting device for a tablet personal computer comprising a baseplate, a locating plate for placing the tablet personal computer and a supporting shelf for supporting the locating plate is disclosed. A wireless keyboard wirelessly communicatively coupled to the tablet personal computer is equipped on the baseplate. The supporting shelf comprises a supporting plate and a sliding plate. The first end of the supporting plate is in folding connection with the sliding plate and the second end of the supporting plate is connected with the locating plate. The sliding plate is slideably arranged on the baseplate. When in use, the inclination angle of the locating plate can be adjusted through sliding the sliding plate. In such a way, the inclination angle of the tablet personal computer can be further adjusted, so as to adapt the requirements of different people and different locations.

### FIELD OF THE INVENTION

The present invention relates to a supporting device for an electrical product, more particularly, to a supporting device for a tablet personal computer.

### BACKGROUND OF THE INVENTION

While providing functions such as browsing internets, receiving and sending Emails, reading electrical books, playing audio/video documents and so on, the tablet personal computer itself is a hand-held device receiving flat-panel touch control input and requiring no keyboard input. Accordingly, the tablet personal computer only has several keys in total, which results in inconvenience word input when operating. Thus, an additional keyboard is required to coordinate with the tablet personal computer. No supporting device or base is arranged at the shell of the tablet personal computer, so an additional supporting device for supporting the keyboard is needed when the tablet personal computer and the keyboard work together. Generally, the existing supporting device has no keyboard. Meanwhile, some supporting devices provided with keyboards are large both in width between the front and the back of the whole device and in volume due to the effect of the width between the front and the back of the keyboard and the requirement of supporting the tablet personal computer, making it inconvenient to carry. Moreover, the placing angle of the tablet personal computer can not be adjusted conveniently.

### SUMMARY OF THE INVENTION

The objective of the present invention is to provide a supporting device for a tablet personal computer, which is provided with a keyboard, capable of making it easy to adjust the placing angle of the tablet personal computer, small in volume and convenient to carry, aiming at the above mentioned defects of the prior art.

Technical solution employed by present invention for solving its technical problem is constructing a supporting device for a tablet personal computer comprising a baseplate, a locating plate for placing the tablet personal computer and a supporting shelf for supporting the locating plate; wherein a wireless keyboard wirelessly communicatively coupled to the tablet personal computer is equipped on the baseplate, the supporting shelf comprises a supporting plate and a sliding plate, a first end of the supporting plate is in folding connection with the sliding plate and a second end of the supporting plate is connected with the locating plate, when in use, the supporting plate and the locating plate form a herringbone together, the sliding plate is slideably arranged on the baseplate.

Advantageously, the first end of the supporting plate and a second end of the sliding plate are articulated.

Advantageously, the baseplate comprises an upper baseplate and a lower baseplate fixedly connected, a first end of the sliding plate is slideably arranged in a guide slot between the upper baseplate and lower baseplate, the second end of the sliding plate is in folding connection with the first end of the supporting plate.

Advantageously, a supporting platform is arranged on a lower surface of the second end of the sliding plate, a locating slot coordinated with the supporting platform is arranged on the lower baseplate.

Advantageously, a rotation element is rotatably arranged on the locating plate and articulated with the second end of the supporting plate.

Advantageously, the rotation element comprises a front rotary table and a back rotary table arranged at two sides of the locating plate respectively, wherein, the front rotary table and back rotary table are fixedly connected, the locating plate is provided with a rotating aperture, a peripheral edge of which is located between the front rotary table and back rotary table, and the back rotary table is articulated with the second end of the supporting plate.

Advantageously, the peripheral edge of the rotating aperture is provided with an annular protruding, and the back rotary table is provided with an annular slot coordinated with the annular protruding.

Advantageously, the back rotary table and the locating plate are both provided with grooves coordinated with the supporting plate.

Advantageously, an upper surface of the placing plate is provided with a restricting slot, the locating plate is provided with a restricting lug arranged at an edge thereof and coordinated with the restricting slot.

Advantageously, a front end of the locating plate and a front end of the baseplate are buckled together.

When in use, the inclination angle of the locating plate in the supporting device for an electrical product according to present invention can be adjusted through sliding the sliding plate in the condition that the contact point between the lower end of the location plate and the baseplate never changes. In such a way, the inclination angle of the tablet personal computer can be further adjusted, so as to adapt the requirements of different people and different locations and improve the comfort degree of the usage of the user, then make the whole device more humanization. The width between the front and the back of the baseplate can be further extended by sliding the sliding plate frontward and backward, so that while supporting the locating plate effectively, the width between the front and the back of the whole device can be decreased and the volume of the whole device also can be reduced, making the device more convenient.

### BRIEF DESCRIPTION OF THE DRAWINGS

Hereinafter, embodiments of present invention will be described in detail with reference to the accompanying drawings, wherein:

FIG. 1 is an exploded structure view of the supporting device for a tablet personal computer according to a preferable embodiment of present invention;

FIG. 2 is a diagram showing the connection between the rotation element and the locating plate in the supporting device for a tablet personal computer according to a preferable embodiment of present invention;

FIG. 3 is a structure cutaway view of the rotation element and the locating plate in the supporting device for a tablet personal computer according to a preferable embodiment of present invention;

FIG. 4 is a structure diagram of the baseplate in the supporting device for a tablet personal computer according to a preferable embodiment of present invention;

FIG. 5 is a side structure diagram of the supporting device for a tablet personal computer according to a preferable embodiment of present invention;

FIG. 6 is a structure diagram of the supporting device for a tablet personal computer after rotating the locating plate for 90 degree according to a preferable embodiment of present invention.

### DETAILED DESCRIPTION OF THE PREFERRED EMBODIMENT

Hereinafter, embodiments of the present invention will be described in detail with reference to the accompanying drawings for better understanding of the technical feature, object and effect of present invention.

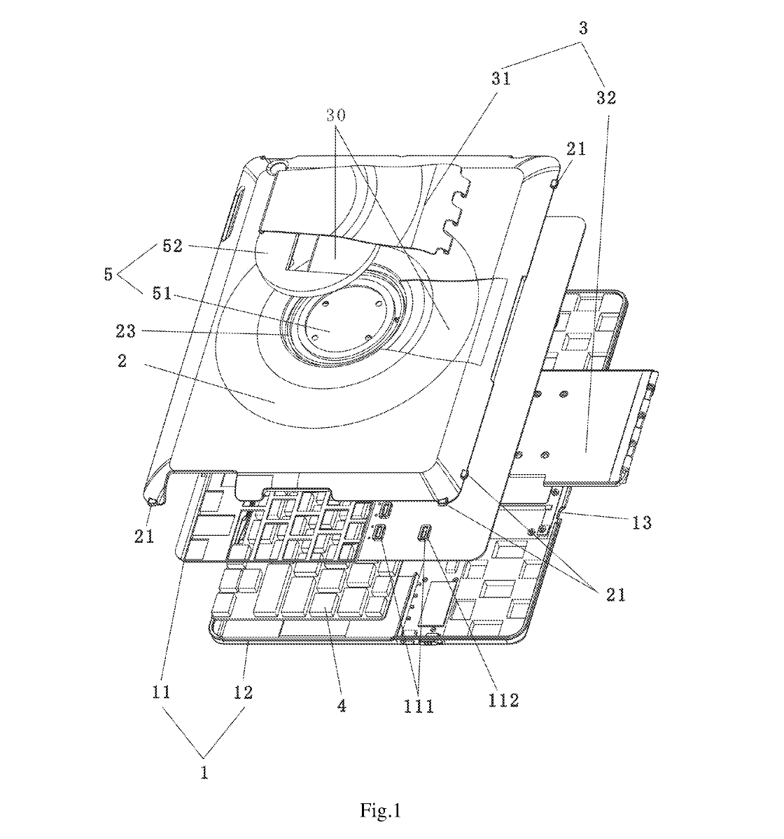

As shown in FIG. 1, the supporting device for a tablet personal computer according to a preferable embodiment of present invention comprises a baseplate 1, a locating plate 2 for placing the tablet personal computer and a supporting shelf 3 for supporting the locating plate 2. The supporting shelf 3 comprises a supporting plate 31 and a sliding plate 32. The first end of the supporting plate 31 is in folding connection with the sliding plate 32 and the second end of the supporting plate 31 is connected with the locating plate 2. When in use, the inclination angle of the locating plate 2 can be adjusted through sliding the sliding plate 32 in the condition that the contact point between the lower end of the location plate 2 and the baseplate 1 never changes. In such a way, the inclination angle of the tablet personal computer can be further adjusted, so as to adapt the requirements of different people and different locations and improve the comfort degree of the usage of the user, then make the whole device more humanization. The width between the front and the back of the baseplate 1 can be further extended by sliding the sliding plate 32 frontward and backward, so that while supporting the locating plate 2 effectively, the width between the front and the back of the whole device can be decreased and the volume of the whole device also can be reduced, making the device more convenient.

A wireless keyboard 4 wirelessly communicatively coupled to the tablet personal computer is equipped on the baseplate 1. Wireless communication can be carried out after placing the tablet personal computer on the locating plate 2 and turning on the wireless keyboard 4, which is convenient in use. Advantageously, wireless communication connection between wireless keyboard 4 and tablet personal computer can be implemented through Bluetooth.

Advantageously, as shown in FIG. 5, the first end of the supporting plate 31 and the second end of the sliding plate 32 are articulated, which is simple in structure and suitable for manufacturing. In such a way, the supporting plate 31 is in folding connection with the sliding plate 32, making it convenient to fold the whole supporting device for a tablet personal computer and to move the supporting plate 31 correspondingly when sliding the sliding plate 32. Wherein, in another embodiment, the supporting plate 31 and the sliding plate 32 are connected through an additional foldable connecting element or soft material such as leather and so on, so as to carry out the folding between the supporting plate 31 and the sliding plate 32.

As shown in FIG. 1, the baseplate 1 comprises an upper baseplate 11 and a lower baseplate 12 fixedly connected. The first end of the sliding plate 32 is slideably arranged in a guide slot between the upper baseplate 11 and lower baseplate 12. The second end of the sliding plate 32 is in folding connection with the first end of the supporting plate 31. By arranging the sliding plate 32 between the upper baseplate 11 and lower baseplate 12, the connection strength between the sliding plate 32 and baseplate 1, as well as the sliding stability of the sliding plate 32 in the guide slot, can be improved.

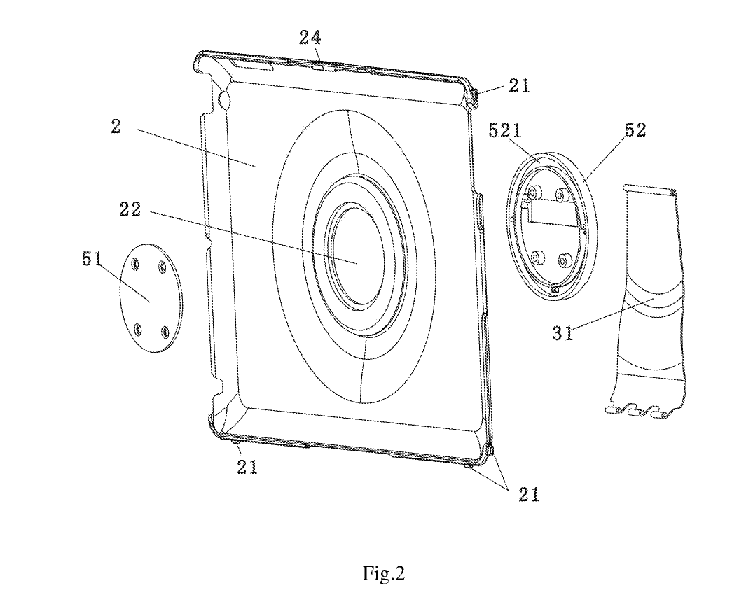

As shown in FIG. 5, a supporting platform 321 is arranged on a lower surface of the second end of the sliding plate 32. As the second end of the sliding plate 32 is connected with the supporting plate 31, the second end of the sliding plate 32 will support the tablet personal computer. When the sliding plate 32 slides out of the guide slot, the supporting platform 321 is used to support the second end of the sliding plate 32 for improving the stability of the device in use. As shown in FIG. 2, a locating slot 13 coordinated with the supporting platform 321 is arranged on the lower baseplate 12. When the slide plate 32 slides into the guide slot, the supporting platform 321 is retracting into the locating slot 13, thus making the shape of the supporting device compact.

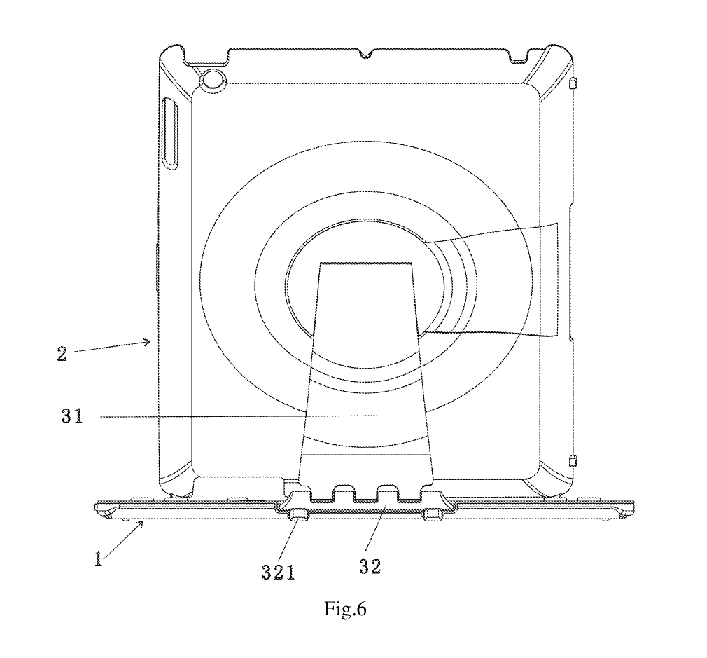

As shown in FIG. 1, a rotation element 5 is rotatably arranged on the locating plate 2 and articulated with the second end of the supporting plate 31. The supporting plate 31 is connected with the locating plate through the rotation element 5. As shown in FIG. 6, when in use, the locating plate 2 can rotate related to the supporting plate 31 in the vertical plane. In such a way, the locating plate 2 can coordinate the transverse and vertical placement of the tablet personal computer, thus improving the practicability of the supporting device according present invention.

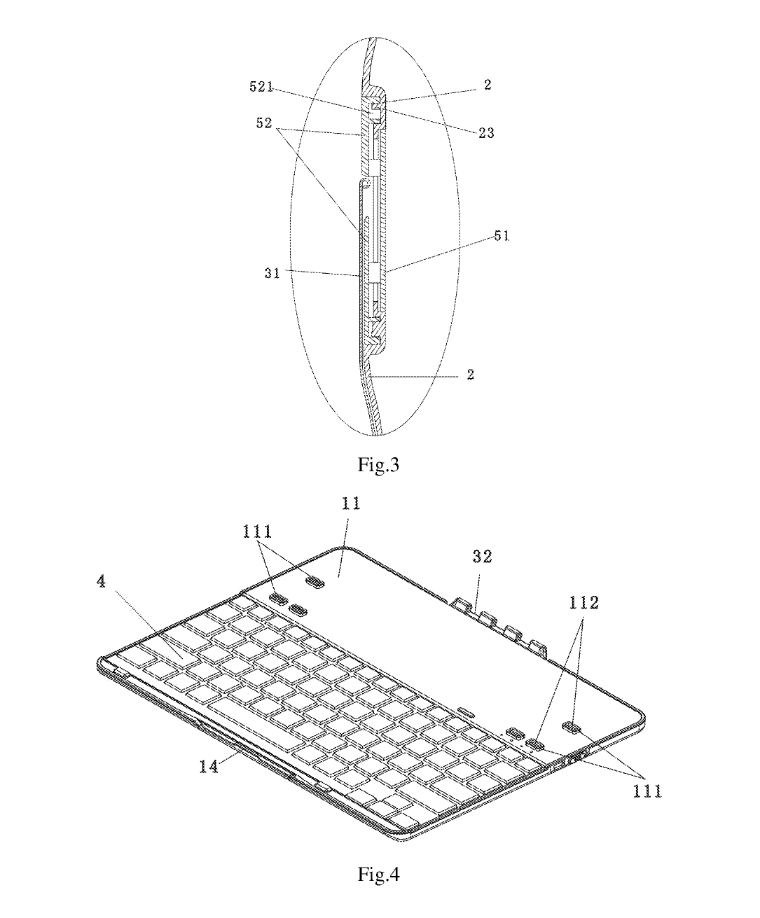

Combining FIG. 1, FIG. 2 and FIG. 3, we can see that the rotation element 5 comprises a front rotary table 51 and a back rotary table 52 arranged at two sides of the locating plate 2 respectively. The front rotary table 51 and the back rotary table 52 are fixedly connected. The locating plate 2 is provided with a rotating aperture 22, a peripheral edge of which is located between the front rotary table 51 and back rotary table 52, enabling the rotation element 5 to rotate in the rotating aperture 22. In such a way, the locating plate 2 is capable of rotating about the rotation element 5. The back rotary table 52 is articulated with the second end of the supporting plate 31.

Furthermore, the peripheral edge of the rotating aperture 22 is provided with an annular protruding 23, and the back rotary table 52 is provided with an annular slot 521 coordinated with the annular protruding 23. When the back rotary table 52 is connected with the locating plate 2, the annular protruding 23 is located inside the annular slot 521 so as to facilitate the relative rotation between the rotation element 5 and the locating plate 2. Meanwhile, ball bearing is arranged between the annular slot 521 and the annular protruding 23, so as to facilitate the moving of the locating plate 2. Herein, as another embodiment, the rotation element 5 and the locating plate 2 are connected through a bearing for implementing the relative rotation between the rotation element 5 and the locating plate 2.

As shown in FIG. 1, the back rotary table 52 and the locating plate 2 are both provided with grooves 30 coordinated with the supporting plate 31. When the supporting device for a tablet personal computer is retracted, the supporting plate 31 is retracted into the grooves, which making the outer surface of the whole device compact and beautiful.

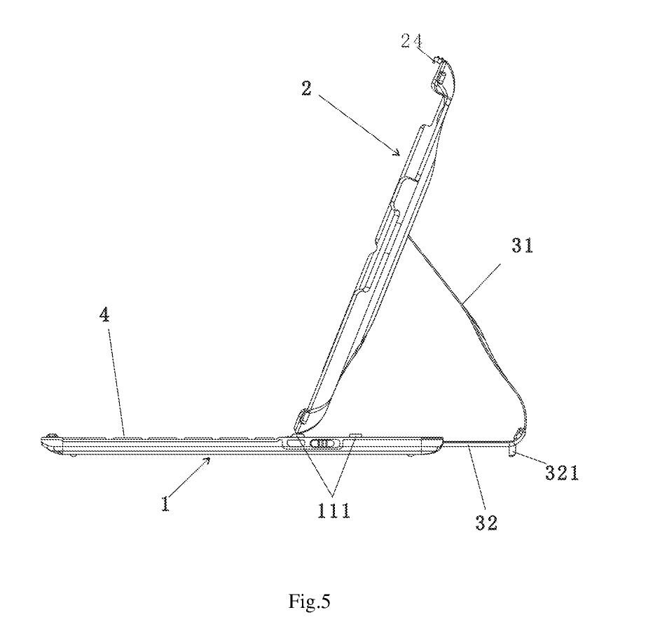

As shown in FIG. 4, an upper surface of the baseplate 1 is provided with a restricting slot 112. More particularly, in present embodiment, the upper surface of the upper baseplate is provided with a lug 111, on which the restricting slot 112 is arranged. Herein, it is also possible that, restricting slot 112 is directly arranged on the baseplate 1. A restricting lug 21 coordinated with the restricting slot 112 is arranged at the edge of the locating plate 2. When in use, the restricting lug 21 is located in the restricting slot 112 so as to guarantee that the lower end of the locating plate 2 will never slide frontward and backward on the upper baseplate 11. In present embodiment, the adjacent edges of the locating plate 2 are both provided with restricting lugs 21, preventing the locating plate from sliding after rotating for 90 degree, so as to adapt different placing location of the tablet personal computer.

In present preferable embodiment, the upper baseplate 11 is provided with two rows of restricting slot 112, each of which is arranged at different location at the front and back of the upper baseplate 11, so as to adjust the location of the locating plate 2 frontward and backward

Combining FIG. 2 and 4, we can see that the front ends of the locating plate 2 and baseplate 1 are buckled together. The supporting shelf 3 is arranged at the back end of the baseplate 1. When retracting the supporting device for a tablet personal computer, the locating plate 2 and baseplate 1 are buckled together so as to guarantee the stability in the retraction state. In present preferable embodiment, the front edge of the locating plate 2 is provided with a hook 24. The front end of the baseplate 1 is provided with a tank 14. Through the cooperation of the hook 24 and tank 14, the locating plate 2 and baseplate 1 are buckled together. Herein, the locating plate 2 and baseplate 1 also can be buckled together through other structure or manner. For example, the hook can be arranged on the baseplate and the tank can be arranged on the locating plate.

The foregoing description of the exemplary embodiments of the invention has been presented only for the purposes of illustration and description and is not intended to be exhaustive or to limit the invention to the precise forms disclosed. Any modifications and variations are possible in light of the above teaching without departing from the protection scope of the present invention.

What we claimed is:

1. A supporting device for a tablet personal computer comprising a baseplate equipped with a wireless keyboard wirelessly communicatively coupled to the tablet personal computer, a locating plate for placing the tablet personal computer, wherein, the supporting device for a tablet personal computer further comprises a supporting shelf for supporting the locating plate;
the supporting shelf comprises a supporting plate and a sliding plate, a first end of the supporting plate is in folding connection with the sliding plate and a second end of the supporting plate is connected with the locating plate, when in use, the supporting plate and the locating plate form a herringbone together, the sliding plate is slideably arranged on the baseplate.

2. The supporting device for a tablet personal computer according to claim 1, wherein, the first end of the supporting plate and a second end of the sliding plate are articulated.

3. The supporting device for a tablet personal computer according to claim 1, wherein, the baseplate comprises an upper baseplate and a lower baseplate fixedly connected, a first end of the sliding plate is slideably arranged in a guide slot between the upper baseplate and lower baseplate, the second end of the sliding plate is in folding connection with the first end of the supporting plate.

4. The supporting device for a tablet personal computer according to claim 3, wherein, a supporting platform is arranged on a lower surface of the second end of the sliding plate, a locating slot coordinated with the supporting platform is arranged on the lower baseplate.

5. The supporting device for a tablet personal computer according to claim 1, wherein, a rotation element is rotatably arranged on the locating plate and is articulated with the second end of the supporting plate.

6. The supporting device for a tablet personal computer according to claim 5, wherein, the rotation element comprises a front rotary table and a back rotary table arranged at two sides of the locating plate respectively, wherein, the front rotary table and the back rotary table are fixedly connected, the locating plate is provided with a rotating aperture, a peripheral edge of which is located between the front rotary table and the back rotary table, and the back rotary table is articulated with the second end of the supporting plate.

7. The supporting device for a tablet personal computer according to claim 6, wherein, the peripheral edge of the rotating aperture is provided with an annular protruding, and the back rotary table is provided with an annular slot coordinated with the annular protruding.

8. The supporting device for a tablet personal computer according to claim 6, wherein, the back rotary table and the locating plate are both provided with grooves coordinated with the supporting plate.

9. The supporting device for a tablet personal computer according to claim 1, wherein, an upper surface of the placing plate is provided with a restricting slot, the locating plate is provided with a restricting lug arranged at an edge thereof and coordinated with the restricting slot.

10. The supporting device for a tablet personal computer according to claim 1, wherein, the front end of the locating plate and the front end of the baseplate are buckled together.
